(19) United States
(12) Patent Application Publication
(10) Pub. No.: US 2026/0209988 A1
(43) Pub. Date: Jul. 23, 2026

(54) SYSTEMS, APPARATUS, AND METHODS FOR MULTI-WAVELENGTH MONITORING FOR SEMICONDUCTOR MANUFACTURING

(71) Applicant: Applied Materials, Inc., Santa Clara, CA (US)

(72) Inventor: Kim Ramkumar VELLORE, San Jose, CA (US)

(21) Appl. No.: 19/035,302

(22) Filed: Jan. 23, 2025

(51) Int. Cl. C30B 25/16; C30B 25/10; G01J 5/00; G01J 5/02; G01J 5/0802

(52) U.S. Cl. CPC C30B 25/16; C30B 25/105; G01J 5/0007; G01J 5/0205; G01J 5/0802

(57) ABSTRACT

The present disclosure relates to systems, apparatus, and methods for multi-wavelength monitoring for semiconductor manufacturing. In one or more embodiments, a system for processing substrates includes a chamber body at least partially defining an internal volume, one or more heat sources configured to heat the internal volume, a substrate support disposed in the internal volume, and a sensor assembly operable to measure energy of a plurality of wavelengths in the internal volume. The sensor assembly includes one or more optical sensors, a movable tray coupled to a motor, and a plurality of filters supported by the movable tray, the motor operable to move the movable tray to move the plurality of filters relative to the one or more optical sensors to respectively align the plurality of filters with at least one of the one or more optical sensors.

### BACKGROUND

### Field

The present disclosure relates to systems, apparatus, and methods for multi-wavelength monitoring for semiconductor manufacturing.

### Description of Related Art

Semiconductor substrates are processed for a wide variety of applications, including the fabrication of integrated devices and microdevices. During processing, various parameters can affect the uniformity of material deposited on the substrate. For example, the temperature of the substrate and/or temperature(s) of processing chamber component(s) can affect deposition uniformity.

It can be difficult to adjust parameters (such as gas flow paths, gas flow rates and gas pressures) for deposition uniformity. As an example, it can be difficult to adjust processing using monitoring from an opposite side of the chamber due to sensing delays. Rotation of the substrate, if used, can exacerbate adjustment difficulties. Relatively low rotation speeds, high pressures, and low flow rates can also exacerbate adjustment difficulties. Moreover, it can be difficult to clean components of processing chambers.

Efforts to address such difficulties can involve difficulties of monitoring temperatures of the substrate and/or chamber components. Efforts can also involve difficulties of monitoring coating of chamber component(s).

Therefore, a need exists for improved processing systems, and related apparatus and methods, that facilitate adjusting process parameters and monitoring temperatures and coating conditions.

### SUMMARY

The present disclosure relates to systems, apparatus, and methods for multi-wavelength monitoring for semiconductor manufacturing.

In one or more embodiments, a system for processing substrates includes a chamber body at least partially defining an internal volume, one or more heat sources configured to heat the internal volume, a substrate support disposed in the internal volume, and a sensor assembly operable to measure energy of a plurality of wavelengths in the internal volume. The sensor assembly includes one or more optical sensors, a movable tray coupled to a motor, and a plurality of filters supported by the movable tray, the motor operable to move the movable tray to move the plurality of filters relative to the one or more optical sensors to respectively align the plurality of filters with at least one of the one or more optical sensors.

In one or more embodiments, a system for processing substrates includes a chamber body at least partially defining an internal volume, one or more heat sources configured to heat the internal volume, and a substrate support disposed in the internal volume. The system includes a sensor assembly operable to measure energy of a plurality of wavelengths in the internal volume. The sensor assembly includes a probe including a view lens oriented toward the substrate support, a camera in optical communication with the probe, a rotatable wheel coupled to a motor, and a plurality of filters supported by the rotatable wheel. The motor is operable to move the rotatable wheel to move the plurality of filters relative to the camera to respectively align the plurality of filters with the camera.

In one or more embodiments, a system for processing substrates includes a chamber body at least partially defining an internal volume, one or more heat sources configured to heat the internal volume, a substrate support disposed in the internal volume, and a sensor assembly operable to measure energy of a plurality of wavelengths in the internal volume. The sensor assembly includes a camera, a rotatable wheel coupled to a motor, and a plurality of filters. The system includes a controller including instructions that, when executed, cause a plurality of operations to be conducted. The plurality of operations include heating a substrate supported at least partially by the substrate support, flowing one or more process gases over the substrate to form one or more layers on the substrate, and rotating the rotatable wheel to shift the respective filters into alignment with an optical path of the camera.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic enlarged view of the processing chamber shown in FIG. 1, according to one or more embodiments.

FIG. 3 illustrates a simplified schematic partial cross-sectional view of a portion of the processing chamber shown in FIG. 1, according to one or more embodiments.

FIG. 4 is schematic partial and enlarged view of the sensor assembly of the processing chamber shown in FIG. 1, according to one or more embodiments.

FIG. 5 is a schematic top view of the movable tray and the filters, according to one or more embodiments.

FIG. 6 is a schematic block diagram view of a method of substrate processing, according to one or more embodiments.

FIG. 7 is a schematic block diagram view of a method of chamber cleaning, according to one or more embodiments.

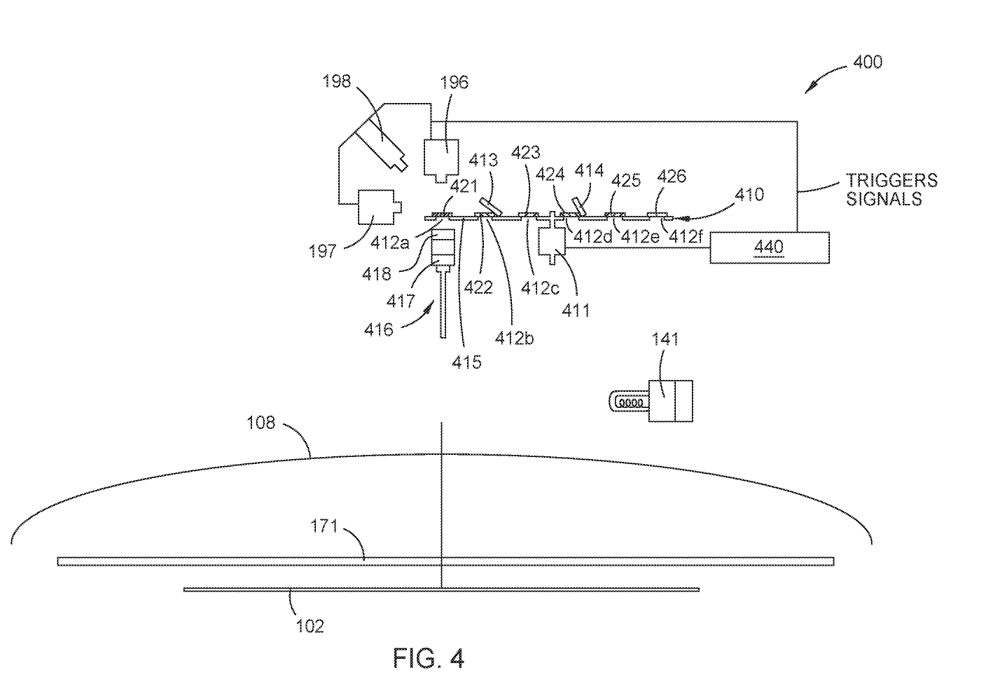

Cross-sectional hatching is omitted from certain components (such as in FIG. 4) for visual clarity purposes.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to systems, apparatus, and methods for multi-wavelength monitoring for semiconductor manufacturing. In one or more embodiments, a plurality of filters corresponding to a plurality of wavelengths are moved past one or more sensors to shift measurements across the plurality of wavelengths.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

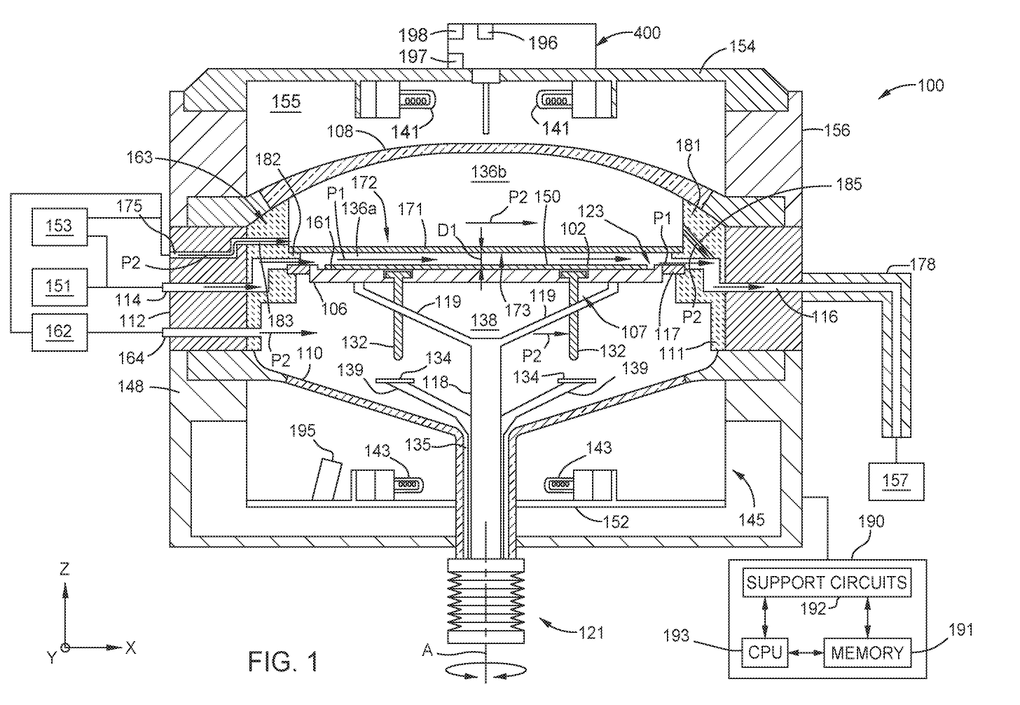

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), a plurality of upper heat sources 141, and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper window 108 and the lower window 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper window and a lid 154. The plurality of upper heat sources 141 form a portion of the upper heat source module 155. The lid 154 includes a plurality of sensors 196, 197, 198 disposed therein or thereon and configured to measures temperature(s) within the processing chamber 100. A lower sensor 195 is configured to measure temperature(s) within the processing chamber 100. In one or more embodiments, each sensor 195, 196, 197, 198 is a pyrometer. In one or more embodiments, each sensor 195, 196, 197, 198 is an optical sensor, such as an optical pyrometer. The present disclosure contemplates that sensors other than pyrometers may be used. Each sensor 195, 196, 197, 198 is a single-wavelength sensor or a multi-wavelength (such as dual-wavelength) sensor. The lower sensor 195 is disposed adjacent to the floor 152. Upper sensors devices 196, 197, 198 are part of a sensor assembly 400 mounted to the lid.

In one or more embodiments, the process chamber 100 includes any one, any two, or any three of the four illustrated sensors 195, 196, 197, 198.

In one or more embodiments, the process chamber 100 includes one or more additional sensors, in addition to the sensors 195, 196, 197, 198. In one or more embodiments, the process chamber 100 may include sensors disposed at different locations and/or with different orientations than the illustrated sensors 195, 196, 197, 198.

The plurality of lower heat sources 143 are disposed between the lower window 110 and a floor 152. The plurality of lower heat sources 143 form a portion of a lower heat source module 145. The upper window 108 is an upper dome and/or is formed of an energy transmissive material, such as quartz. The lower window 110 is a lower dome and/or is formed of an energy transmissive material, such as quartz. The present disclosure contemplates that the upper window 108 and/or the lower window 110 can be in the shape of a dome or can be in another shape, such as flat, concave, or another contour.

An upper volume 136 and a purge volume 138 are formed between the upper window 108 and the lower window 110. The upper volume 136 and the purge volume 138 are part of an internal volume defined at least partially by the upper window 108, the lower window 110, and one or more liners 111, 163.

The internal volume has the substrate support 106 disposed therein. The substrate support 106 includes a top surface on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the upper volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the upper volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (Cl). In one or more embodiments, the one or more process gases P1 include silicon phosphide (SiP) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

The processing chamber 100 includes a plate 171 having a first face 172 and a second face 173 opposing the first face 172. In one or more embodiments, the plate 171 is part of a flow guide structure. The second face 173 faces the substrate support 106. The processing chamber 100 includes the one or more liners 111, 163. An upper liner 163 includes an annular section 181 and one or more ledges 182 extending inwardly relative to the annular section 181. The one or more ledges 182 are configured to support one or more outer regions of the second face 173 of the plate 171. The upper liner 163 includes one or more inlet openings 183 and one or more outlet openings 185. In one or more embodiments, the plate 171 is in the shape of a disc, and the annular section 181 is in the shape of a ring. The plate 171 can be in the shape of a rectangle. The plate 171 divides the upper volume 136 between the substrate support 106 and the upper window 108 into a lower portion 136a and an upper portion 136b. The lower portion 136a is a processing portion. In one or more embodiments, the plate 171 is an isolation plate that fluidly isolates the upper portion 136b from the lower portion 136a.

The flow module 112 (which can be at least part of a sidewall of the processing chamber 100) includes the one or more gas inlets 114 in fluid communication with the lower portion 136a. The flow module 112 includes one or more second gas inlets 175 in fluid communication with the upper portion 136b. The one or more gas inlets 114 are in fluid communication with one or more flow gaps between the upper liner 163 and a lower liner 111. The one or more second gas inlets 175 are in fluid communication with the one or more inlet openings 183 of the upper liner 163.

During a deposition operation (e.g., an epitaxial growth operation), the one or more process gases P1 flow through the one or more gas inlets 114, through the one or more gaps, and into the lower portion 136a to flow over the substrate 102. During the deposition operation, one or more purge gases P2 flow through the one or more second gas inlets 175, through the one or more inlet openings 183 of the lower liner 111, and into the upper portion 136b. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through gaps between the upper liner 163 and the lower liner 111, and through the one or more gas exhaust outlets 116. The one or more purge gases P2 are exhausted through the one or more outlet openings 185, through the same gaps between the upper liner 163 and the lower liner 111, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

The present disclosure also contemplates that the one or more purge gases P2 can be supplied to the purge volume 138 (through the one or more purge gas inlets 164) during the deposition operation, and exhausted from the purge volume 138.

During a cleaning operation, one or more cleaning gases flow through the one or more gas inlets 114, through the one or more gaps (between the upper liner 163 and the lower liner 111), and into the lower portion 136a. During the cleaning operation, one or more cleaning gases also simultaneously flow through the one or more second gas inlets 175, through the one or more inlet openings 183 of the upper liner 163, and into the upper portion 136b. The present disclosure contemplates that the one or more cleaning gases used to clean surfaces adjacent the upper portion 136b can be the same as or different than the one or more cleaning gases used to clean surfaces adjacent the lower portion 136a.

The processing chamber 100 facilitates separating the gases provided to the lower portion 136a from the gases provided to the upper portion 136b, which facilitates parameter adjustability. Additionally, one or more purge gases and one or more cleaning gases can be separately provided to the upper portion 136b to facilitate reduced contamination of the upper window 108 and/or the plate 171.

As shown, a controller 190 is in communication with the processing chamber 100 and is used to control processes and methods, such as the operations of the methods described herein.

The controller 190 is configured to receive data or input as sensor readings from a plurality of sensors. The sensors can include, for example: sensors that monitor growth of layer(s) on the substrate 102; sensors that monitor growth or residue on inner surfaces of chamber components of the processing chamber 100 (such as inner surfaces of the plate 171 and/or the one or more liners 111, 163); and/or sensors that monitor temperatures of the substrate 102, the substrate support 106, the plate 171, and/or the liners 111, 163. The controller 190 is equipped with or in communication with a system model of the processing chamber 100. The system model includes a heating model, a coating model, a rotational position model, and/or a gas flow model. The system model is a program configured to estimate parameters (such as a gas flow rate, a gas pressure, a processing temperature, a rotational position of component(s), a heating profile, a coating condition, and/or a cleaning condition) within the processing chamber 100 throughout a deposition operation and/or a cleaning operation. The controller 190 is further configured to store readings and calculations. The readings and calculations include previous sensor readings, such as any previous sensor readings within the processing chamber 100. The readings and calculations further include the stored calculated values from after the sensor readings are measured by the controller 190 and run through the system model. Therefore, the controller 190 is configured to both retrieve stored readings and calculations as well as save readings and calculations for future use. Maintaining previous readings and calculations enables the controller 190 to adjust the system model over time to reflect a more accurate version of the processing chamber 100.

The controller 190 can monitor, estimate an optimized parameter, detect a coating condition for the plate 171, generate an alert on a display, halt a deposition operation, initiate a chamber downtime period, delay a subsequent iteration of the deposition operation, initiate a cleaning operation, detect a cleaning condition for the plate 171, halt the cleaning operation, adjust a heating power, and/or otherwise adjust the process recipe.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., the coating condition, a pressure for process gases P1, a processing temperature, a heating profile, a flow rate for process gases P1, a pressure for cleaning gases, a flow rate for cleaning gases, and/or a rotational position of a the substrate support 106) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of operations of method 600 and/or the method 700 (described below) to be conducted in relation to the processing chamber 100. The controller 190 and the processing chamber 100 are at least part of a system for processing substrates.

The various operations described herein (such as the operations of the method 600 and/or the method 700) can be conducted automatically using the controller 190, or can be conducted automatically or manually with certain operations conducted by a user.

In one or more embodiments, the controller 190 includes a mass storage device, an input control unit, and a display unit. The controller 190 monitors the temperature of the substrate 102, the temperature of the substrate support 106, the temperature of the plate 171, the process gas flow, and/or the purge gas flow. In one or more embodiments, the controller 190 includes multiple controllers 190, such that the stored readings and calculations and the system model are stored within a separate controller from the controller 190 which controls the operations of the processing chamber 100. In one or more embodiments, all of the system model and the stored readings and calculations are saved within the controller 190.

The controller 190 is configured to control the sensors 195, 196, 197, 198, the deposition, the cleaning, the rotational position, the heating, and gas flow through the processing chamber 100 by providing an output to the controls for the heat sources, the gas flow, and the motion assembly 121. The controls include controls for the sensors 195, 196, 197, 198, the upper heat sources 141, the lower heat sources 143, the process gas source 151, the purge gas source 162, the motion assembly 121, and the exhaust pump 157.

The controller 190 is configured to adjust the output to the controls based on the sensor readings, the system model, and the stored readings and calculations. The controller 190 includes embedded software and a compensation algorithm to calibrate measurements. The controller 190 can include one or more machine learning algorithms and/or artificial intelligence algorithms that estimate optimized parameters for the deposition operations and/or the cleaning operations (such as for adjusting a deposition operation (e.g. the process recipe), halting the deposition operation, initiating a chamber downtime period, delaying a subsequent iteration of the deposition operation, initiating a cleaning operation, halting the cleaning operation, adjusting a heating power, and/or adjusting the cleaning operation). The optimized parameter can include, for example, a pre-determined coating thickness on the plate 171 that initiates a cleaning operation to remove the coating from the plate 171.

The one or more machine learning algorithms and/or artificial intelligence algorithms may implement, adjust and/or refine one or more algorithms, inputs, outputs or variables described above. Additionally or alternatively, the one or more machine learning algorithms and/or artificial intelligence algorithms may rank or prioritize certain aspects of adjustments of the process chamber 100, the method 600, and/or the method 700 relative to other aspects of the process chamber 100, the method 600, and/or the method 700. The one or more machine learning algorithms and/or artificial intelligence algorithms may account for other changes within the processing systems such as hardware replacement and/or degradation. In one or more embodiments, the one or more machine learning algorithms and/or artificial intelligence algorithms account for upstream or downstream changes that may occur in the processing system due to variable changes of the process chamber 100, the method 600, and/or the method 700. For example, if variable “A” is adjusted to cause a change in aspect “B” of the process, and such an adjustment unintentionally causes a change in aspect “C” of the process, then the one or more machine learning algorithms and/or artificial intelligence algorithms may take such a change of aspect “C” into account. In such an embodiment, the one or more machine learning algorithms and/or artificial intelligence algorithms embody predictive aspects related to implementing the process chamber 100, the method 600, and/or the method 700. The predictive aspects can be utilized to preemptively mitigate unintended changes within a processing system.

The one or more machine learning algorithms and/or artificial intelligence algorithms can use, for example, a regression model (such as a linear regression model) or a clustering technique to estimate optimized parameters. The algorithm can be unsupervised or supervised. The one or more machine learning algorithms and/or artificial intelligence algorithms can optimize, for example, a heating power applied to the heat sources 141, 143, a cleaning recipe, and/or a processing recipe. The one or more machine learning algorithms and/or artificial intelligence algorithms can optimize, for example, the pre-determined thickness and/or the second pre-determined thickness discussed herein, a time for initiating a cleaning operation, and/or a time for initiating a deposition operation.

In one or more embodiments, the controller 190 automatically conducts the operations described herein without the use of one or more machine learning algorithms or artificial intelligence algorithms. In one or more embodiments, the controller 190 compares measurements (such as of the reading increase and/or the reading decrease) to data in a look-up table and/or a library to determine if the coating condition and/or the cleaning condition are detected. The controller 190 can stored measurements as data in the look-up table and/or the library.

The present disclosure contemplated that component(s) can be omitted from the processing chamber 100. For example, the plate 171 can be omitted from the processing chamber 100.

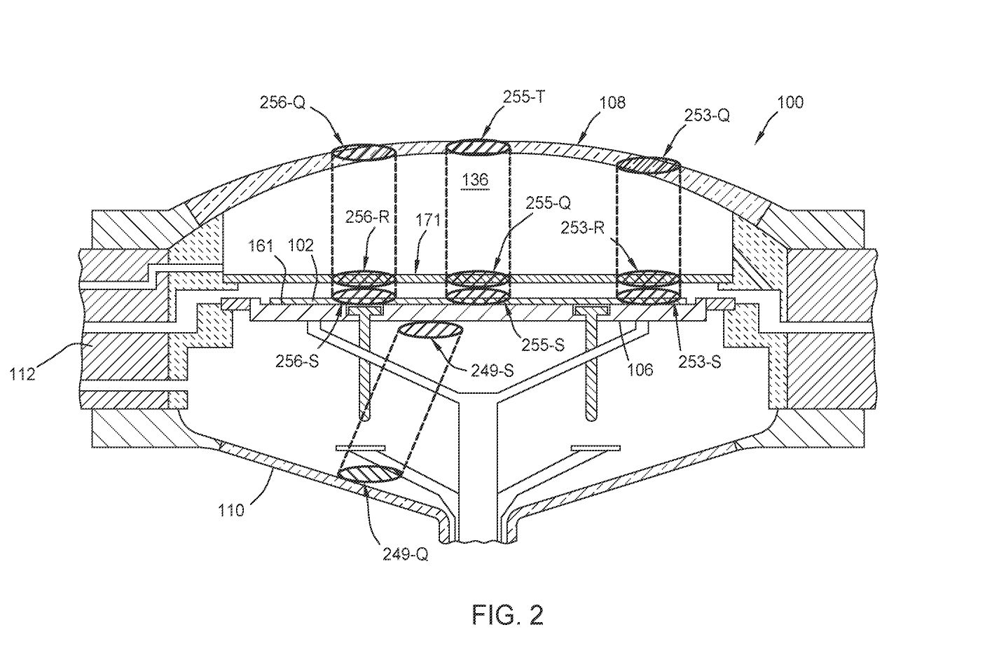

FIG. 2 is a schematic enlarged view of the processing chamber 100 shown in FIG. 1, according to one or more embodiments. The substrate support 106 has an upper surface 161 (e.g., a support surface) and a lower surface 169.

FIG. 2 also illustrates a plurality of temperature measurement sites 249-Q, 249-S, 253-Q, 253-R, 253-S, 255-Q, 255-S, 256-Q, 256-R, 256-S. For example, in one or more embodiments, the lower sensor 195 (FIG. 1) is configured to measure energy (e.g., radiation) at site 249-Q (e.g., at a middle peripheral region of the lower window 110) and/or site 249-S (e.g., at a middle peripheral region of the lower surface 169 of the substrate support 106). In one or more embodiments, upper sensors 196-198 (FIG. 1) is configured to measure temperatures at site 255-Q (e.g., at a central region of the plate 171), site 255-T (e.g., at a central region of the upper window 108), and/or site 255-S (e.g., at a central region of the substrate 102 and/or a central region of the upper surface 161 of the substrate support 106). The present disclosure contemplates that the sensor assembly 400 (FIG. 1) can move to measure different sites. For example, the sensor assembly 400 can move such that the upper sensors 196-198 measure energy at site 253-Q (e.g., at an outer peripheral region of the upper window 108), at site 253-R (e.g., at an outer peripheral region of the plate 171), and/or site 253-S (e.g., at an outer peripheral region of the substrate 102 and/or an outer peripheral region of the upper surface 161 of the substrate support 106). As another example, the sensor assembly 400 can move such that the upper sensors 196-198 measure energy at site 256-Q (e.g., at an outer peripheral region of the upper window 108), at site 256-R (e.g., at an outer peripheral region of the plate 171), and/or site 256-S (e.g., at an outer peripheral region of the substrate 102 and/or an outer peripheral region of the upper surface 161 of the substrate support 106).

The sensors 195, 196, 197, 198 may be positioned and/or oriented differently than what is shown in FIG. 1 and FIG. 2, while still capable of measuring temperatures at a site on the plate 171, a site on one or more of the windows (e.g., upper window 108 and/or lower window 110), and/or a site on one of the surfaces of substrates support 106 (e.g., upper surface 161 and/or lower surface 169) and/or the substrate 102. Each of the sensors 195, 196, 197, 198 may be adapted to detect energy (e.g., radiation, such as light) at two or more (such as three or more) different wavelength ranges. For example, in one or more embodiments the two or more wavelength ranges of one or more of the upper sensors 196, 197, 198 are selected to be (1) a wavelength range at which the plate 171 is absorptive (e.g., about 2.5 microns to about 3.0 microns, such as about 2.7 microns), (2) a wavelength range at which the substrate support 106 and/or the substrate 102 is absorptive (e.g., about 3.1 microns to about 3.5 microns, such as about 3.3 microns), (3) a wavelength range at which the upper window 108 and/or the lower window 110 is absorptive (e.g., about 4.5 microns to about 5.5 microns, such as about 5.0 microns), and/or (4) a wavelength at which the upper heat sources 141 and/or the lower heat sources 143 are absorptive (e.g., about 0.8 microns to about 1.4 microns, such as 1.1 microns).

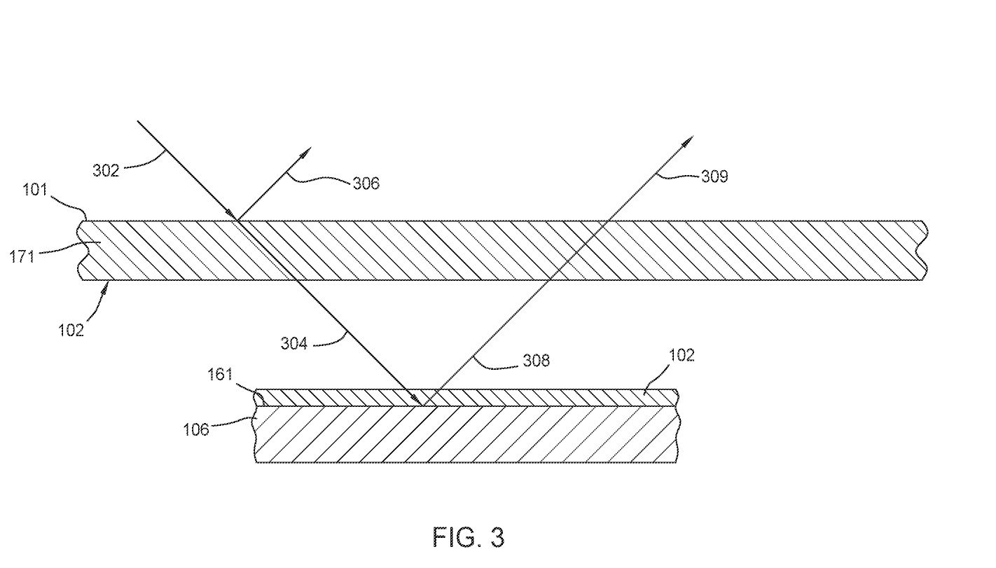

FIG. 3 illustrates a simplified schematic partial cross-sectional view of a portion of the processing chamber 100 shown in FIG. 1, according to one or more embodiments. As illustrated, temperature measurement at each of the sites 249-Q, 249-S, 253-Q, 253-R, 253-S, 255-Q, 255-S, 256-Q, 256-R, and 256-S may be conducted using one or more radiation beams. In one or more embodiments, each of the sensors 195, 196, 197, 198 is configured to emit one or more radiation beams and receive one or more reflected radiation beams. In FIG. 3, a radiation beam 302 may be emitted by the first upper sensor 196. At the first face 172 of the plate 171, a portion of the radiation beam 302 may be reflected as radiation beam 306. Another portion of radiation beam 302 may be transmitted as radiation beam 304. It should be appreciated that the reflected portion and the transmitted portion may be of differing wavelengths, depending on the material and the temperature of the plate 171. For example, reflected radiation beam 306 may have a wavelength in the range of about 2.5 microns to about 3.5 microns. The first upper sensor 196 is configured to receive the reflected radiation beam 306 and measure the intensity of the radiation beam 306. For example, the first upper sensor 196 may be configured to receive and measure, at least, radiation in the wavelength range of about 2.5 microns to about 3.5 microns. At the upper surface 161 of substrate support 106, a portion of radiation beam 304 may be reflected as radiation beam 308. Moreover, a portion of radiation beam 308 may be once again transmitted through upper window 108, resulting in radiation beam 309. It should be appreciated that the reflected portion (e.g., radiation beam 308) and the reflected-transmitted portion (e.g., radiation beam 309) may each be of certain wavelength, depending on the materials and the temperatures of the substrate support 106 and the plate 171. For example, radiation beam 309 may have a wavelength in the range of about 3.1 microns to about 3.5 microns. The first upper sensor 196 is configured to receive the transmitted-reflected-transmitted radiation beam 309 and measure the intensity of the radiation beam 309. For example, the first upper sensor 196 may be configured to receive and measure, at least, radiation in the wavelength range of about 3.1 microns to about 3.5 microns.

In one or more embodiments, one or more of the sensors 195, 196, 197, 198 may measure more than two (such as three or more) different wavelengths (or wavelength ranges) simultaneously. For example, one or more of the sensors 195, 196, 197, 198 may contemporaneously measure radiation in the about 3.1 micron to about 3.5 micron range, the about 2.5 micron to about 3.0 micron range, and the about 4.5 micron to about 5.5 micron range.

The energy measurements made by each of the sensors 195, 196, 197, 198 are used to monitor temperatures and/or film deposition thicknesses within the process chamber 100. Moreover, the measurements may be utilized to assess operational states (such as coating conditions and/or cleaning conditions) of the process chamber 100. For example, differences in temperature measurements may be utilized to detect reactant coating of the plate 171, the upper window 108, and/or the lower window 110. Such coating detection may be obtained without opening process chamber 100 for process and/or clean optimizations.

In relation to FIGS. 1 and 2, the upper window 108 includes a first quartz and the plate 171 includes a second quartz. The first quartz has a first hydroxyl concentration of less than 100 parts-per-million ppm). In one or more embodiments, the first hydroxyl concentration is 30 ppm or less, such as within a range of about 5 ppm to about 30 ppm. The second quartz has a second hydroxyl concentration of more than 750 parts-per-million (ppm). In one or more embodiments, the second hydroxyl concentration is 900 ppm or more. In one or more embodiments, the upper window 108 is formed of the first quartz and the plate 171 is formed of the second quartz. Other window(s), such as the lower window 110, can include the first quartz. For example, the lower window 110 can be formed of the first quartz. Using the first quartz and the second quartz facilitates accurately and efficiently measuring temperatures of the plate 171 and the substrate support 106 (and/or the substrate 102) during processing and facilitates accurately and efficiently detecting the coating condition for the plate 171. As an example, the plate 171 having the higher second hydroxyl concentration facilitates accurately and efficiently measuring temperatures and/or coating conditions for the plate 171 using the second wavelength. Using the first quartz and the second quartz facilitates enhanced signal-to-noise ratios for the measurements. Using the first quartz, thermal non-uniformities affected by temperature gradients of the upper window 108 are reduced or eliminated. For example, gradients of the hydroxyl concentration across a diameter of the first quartz are reduced or eliminated to facilitate enhanced heating uniformity. As recited herein, the hydroxyl concentration refers to a parts-per-million (ppm) measurement of hydroxyl groups (e.g., groups including an oxygen atom covalently bonded to a hydrogen atom) in or on the respective quartz material. In one or more embodiments, the ppm measurement of the hydroxyl concentration is a measured concentration of hydroxyl groups relative to all other materials (such as contaminants and/or quartz) present on the respective quartz surfaces of the first quartz or the second quartz. In one or more embodiments, the measurement of the hydroxyl concentration is conducted by X-ray photoelectron spectroscopy (XPS) and provided in the unit of ppm. The present disclosure contemplates that other measurement techniques, such as glow discharge mass spectroscopy (GDMS), may be used to measure the ppm values of the hydroxyl concentration.

The hydroxyl concentrations can be affected, for example, by the water content and/or contamination content in the respective first quartz or second quartz. The higher hydroxyl concentration of the second quartz involves a lower transmission of energy having the second wavelength. The higher hydroxyl concentration of the second quartz involves a higher transmission of energy having the first wavelength. The first quartz is fused quartz, such as electrically fused quartz. The second quartz is synthetic quartz, such as quartz formed using a soot process. In one or more embodiments, the upper window 108 is a first quartz plate, the plate 171 is a second quartz plate, and the lower window 110 is a third quartz plate.

FIG. 4 is schematic partial and enlarged view of the sensor assembly 400 of the processing chamber 100 shown in FIG. 1, according to one or more embodiments.

The sensor assembly 400 is operable to measure energy of a plurality of wavelengths in the internal volume of the processing chamber 100. The sensor assembly 400 includes one or more optical sensors 196-198 (three are shown), a movable tray 410 coupled to a motor 411 (e.g., a spin motor), and a plurality of filters 421-426 supported by the movable tray 410. The motor 411 is operable to move the movable tray 410 to move the plurality of filters 421-426 relative to the one or more optical sensors 196-198 to respectively align the plurality of filters 421-426 with at least one of the one or more optical sensors 196-198. In one or more embodiments, the movable tray 410 is a rotatable wheel.

The plurality of filters 421-426 include a first filter 421 configured to transmit a first wavelength within a range of 2.5 microns to 3.0 microns (such as about 2.7 microns), a second filter 422 configured to transmit a second wavelength within a range of 4.5 microns to 5.5 microns (such as about 5.0 microns), a third filter configured to transmit a third wavelength within a range of 0.8 microns to 1.4 microns (such as about 1.1 microns), and a fourth filter configured to transmit a fourth wavelength within a range of 3.1 microns to 3.5 microns (such as about 3.3 microns). In one or more embodiments, the filters 421-426 include a red lens, a green lens, and a blue lens. The filters 421-426 can include lenses of other colors.

The movable tray 410 includes a plurality of holes 412a-412f disposed below the plurality of filters 421-426. The movable tray 410 includes a mirror 413 and a second mirror 414 oriented at an angle relative to a plate 415 of the movable tray 410. The mirror 413 and/or the second mirror 414 respectively extend above at least one of the plurality of filters 421-426. The mirror 413 and/or the second mirror 414 respectively include a reflective surface that faces the respective filter 421-426. The reflective surface can include for example, gold, silver, polished aluminum, and/or polished stainless steel. Other materials are contemplated for the reflective surface. In one or more embodiments, the second mirror 414 is oriented at a larger angle relative to the plate 415 such that the mirror 413 directs energy to the second optical sensor 197 and the second mirror 414 directs energy to the third optical sensor 198.

The sensor assembly 400 includes a probe 416 aligned with at least one of the plurality of filters 421-426. The movable tray 410 is movable relative to the probe 416. For example, the movable tray 410 rotates the filters 421-426 past the probe 416. The probe 416 comprises a view lens 417 oriented toward the substrate support 106, and a focus lens 418 disposed between the view lens 417 and the movable tray 410. The focus lens 418 is movable (e.g., rotatable) to alter a focal point of energy collected from the internal volume of the processing chamber 100 and transmitted to at least one of the one or more optical sensors 196-198. In one or more embodiments, the view lens 417 is a fisheye lens, and the probe 416 is a wide spectrum borescope.

The one or more optical sensors 196-198 are respectively operable to measure energy (such as radiation, for example infrared radiation). In the implementation shown in FIG. 4, a first optical sensor 196 includes a camera in optical communication with the probe 416, a second optical sensor 197 includes a second camera in optical communication with the probe 416, and a third optical sensor 198 includes a pyrometer in optical communication with the probe 416. In one or more embodiments, the first optical sensor 196 (e.g., the camera) includes a graphene sensor (e.g., a graphene transducer) operable to sense energy within a wavelength range that is 400 nm to higher than 5.0 microns (such as 400 nm to 8.0 microns). In one or more embodiments, the first optical sensor 196 (e.g., the camera) is operable to sense energy within a wavelength range of 400 nm to 3.0 microns (such as 400 nm to 1.9 microns), and the second optical sensor 197 (e.g., the second camera) is operable to sense energy within a wavelength range of 70 0nm to 8.0 microns (such as 700 nm to 5.0 microns).

The present disclosure contemplates that the readings of the optical sensors 196-198 can be used to correct each other. For example, a pyrometer (e.g., 198) can be used to measure an absolute value temperature at a region of a substrate, and the absolute value temperature can be compared to a measurement of the same region of an image taken by a camera (e.g., 196 and/or 197) to correct temperature measurement of the same region in the image. The same correction factor determined using the absolute value temperature can be applied to the other regions of the substrate in the image to correct an entirety of the substrate. As an example, a substrate map can be corrected in the image. As such, an entirety of a substrate map can be corrected to read absolute temperature using the absolute value temperature measured by the pyrometer. A center-to-edge substrate temperature profile can be corrected in the image. Emissivities and/or changes in emissivity in the images can be used to determine the temperature measurements in the images.

A different number of optical sensors may be used. In one or more embodiments, the first and second optical sensors 196, 197 are used while the third optical sensor 198 is omitted. In one or more embodiments, the first optical sensor 196 is used while the second and third optical sensors 197, 198 are omitted.

The temperature measurements and/or image intensity measurements taken using the optical sensors 196-198 can indicate a temperature and/or a film thickness. For example, a temperature change in the measurements can indicate a non-uniformity of film growth and/or a non-uniformity of cleaning.

A motor controller 440 is coupled to the motor 411, and the motor controller 440 can sync the rotational position of the movable tray 410 with the optical sensors 196-198 such that when one of the filters 421-426 is aligned with the probe 416, the motor controller 440 sends trigger signals to the optical sensor 196, 197, or 198 that corresponds to the aligned filter such that the corresponding optical sensor captures a measurement when the filter is aligned.

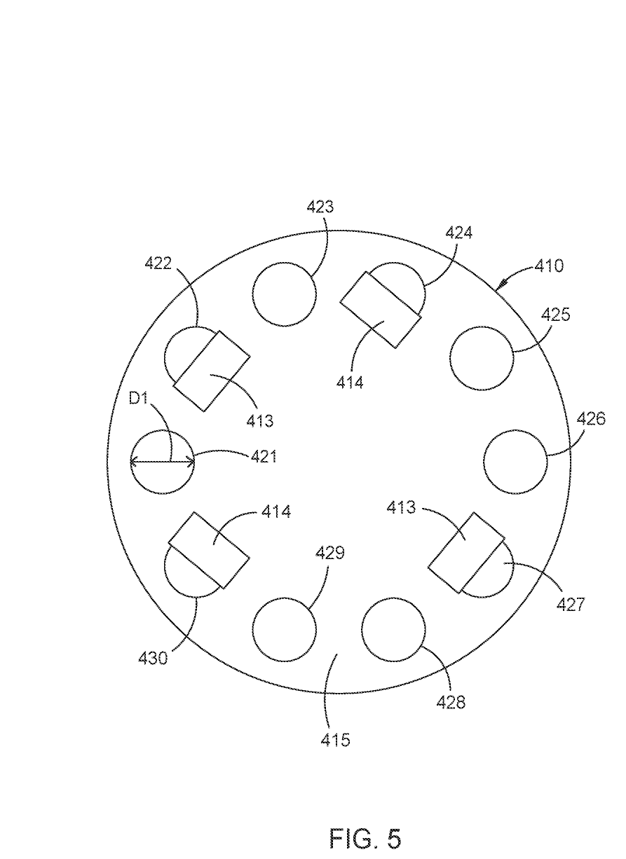

FIG. 5 is a schematic top view of the movable tray 410 and the filters 421-426, according to one or more embodiments.

FIG. 5 shows additional filters 427-430 for a total of ten filters 421-430. The filters 421-430 are azimuthally spaced from each other along the plate 415 of the movable tray 410. The filters 421-430 respectively have a major dimension D1 (such as a diameter) that is within a range of 10 mm to 100m. For example, the major dimension D1 can be about 12.5 mm, about 25 mm, about 49 mm, about 50 mm, about 55 mm, about 62 mm, about 67 mm, about 72 mm, about 77 mm, and/or about 82 mm. In one or more embodiments, the major dimension D1 is about 25 mm or about 50 mm. The openings 412a-412f under the filters 421-430 respectively have a second major dimension (such as a second diameter) that is within a range of 5 mm to 100m. In one or more embodiments, the second major dimension is less than the major dimension D1.

The present disclosure contemplates that the major dimension D1 and/or the second major dimension can vary, for example, depending on the rotation speed of the movable tray 410.

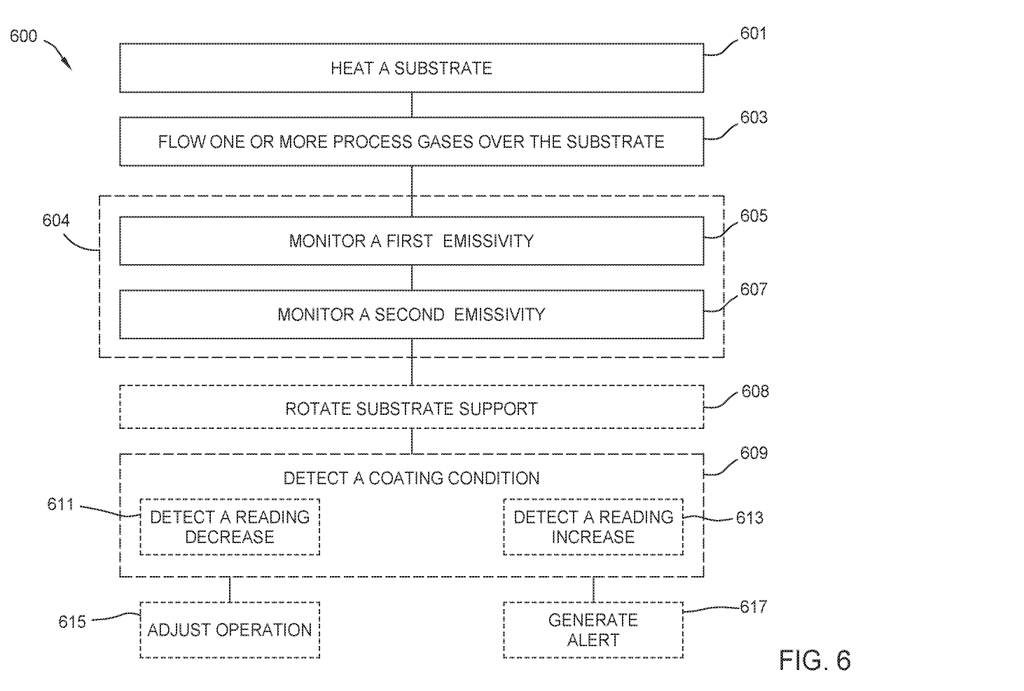

FIG. 6 is a schematic block diagram view of a method 600 of substrate processing, according to one or more embodiments. The method 600 is described in relation to the sensor assembly 400 shown in FIGS. 4 and 5. The present disclosure contemplates that the method 600 can be conducted in relation to other systems and apparatus.

Operation 601 of the method 600 includes heating a substrate supported at least partially by a substrate support. In one or more embodiments, the substrate is positioned on the substrate support. In one or more embodiments, the substrate is positioned on a substrate carrier that is positioned on the substrate support.

Operation 603 includes flowing one or more process gases over the substrate to form one or more layers on the substrate. The flowing of the one or more process gases over the substrate includes guiding the one or more process gases through a gap between the substrate and the volume boundary. In one or more embodiments, the volume boundary is a ceiling. The ceiling can be defined by the second face 173 of the plate 171, for example.

Operation 605 includes monitoring a first emissivity of one or more heat sources using a wavelength (e.g., of 0.8 microns to 1.4 microns) transmitted through a first filter of the filters 621-630. The one or more heat sources can be used for the heating in operation 601.

Operation 607 includes monitoring a second emissivity of the substrate or the substrate support using a second wavelength (e.g., of 3.1 microns to 3.5 microns) transmitted through a second filter of the filters 621-630. In one or more embodiments, the first emissivity and/or second emissivity are monitored and used as part of processing map(s).

In one or more embodiments, operation 605 and 607 are a part of operation 604, which includes rotating the movable tray 410 to shift the respective filters 621-630 into alignment with an optical path of at least one of the optical sensors 196-198 (such as the camera of the first optical sensor 196 and/or the camera of the second optical sensor 197).

Optional operation 608 includes rotating the substrate support at a first speed that is greater than a second speed of the movable tray 410. In one or more embodiments the second speed (e.g., in rotations-per-minute) of the movable tray 410 is equal to or lesser than a value, and the value is equal to a frame rate of at least one of the optical sensors 196-198 (such as the camera of the first optical sensor 196) multiplied by a number of the plurality of filters 621-630 that are being used for monitoring.

Optional operation 609 includes detecting a coating condition for the plate. In one or more embodiments, the detecting of the coating condition includes (at operation 611) detecting a reading decrease through one of the filters 621-630, and (at operation 613) detecting a reading increase through another of the filters 621-630 at the same radial location of the reading decrease. In one or more embodiments, the coating condition is a pre-determined thickness by which the second face 173 and/or the first face 172 of the plate 171 is coated by reactive process gases.

Optional operation 615 includes an adjusting operation. The adjusting can include one or more of: adjusting an operating parameter (such as an input power supplied to at least one of the heat sources of the chamber); halting the deposition of operation 603, initiating a chamber downtime period; initiating a preventive maintenance operation (such as including an open chamber operation); delaying a subsequent iteration of the deposition, and/or initiating a cleaning operation using a cleaning recipe (such as the operation 703 of the method 700 to clean the chamber).

Optional operation 617 includes generating an alert. For example, the alert may indicate a cleaning instruction for the plate. In one or more embodiments, the cleaning instruction instructs an operator (such as on a display of a user interface) to mitigate coating on the plate. The plate may be cleaned before the buildup degrades processing efficiency. In one or more embodiments, the cleaning instruction provides the operator with an estimate of the coating progression, such as the remaining useful chamber operation time before severe degradation of processing efficiency. The operator may use such estimate of the coating progression in order to plan and execute appropriate maintenance activities to reduce machine downtime, reduce costs and resource expenditure, and increase throughput of substrates using the process chamber.

The present disclosure contemplates that the method 600 can be used to predict when a coating condition will next occur, which can be used to predict how long the upper window 108 and/or the plate 171 can undergo processing before cleaning is conducted. The method 600 can be used to predict when a cleaning condition will next occur, which can be used to predicted how long it will take to cleaning a chamber component (such as the upper window 108 and/or the plate 171). As an example, measurements and calculations of the method 600 can be saved and optimized to make predictions.

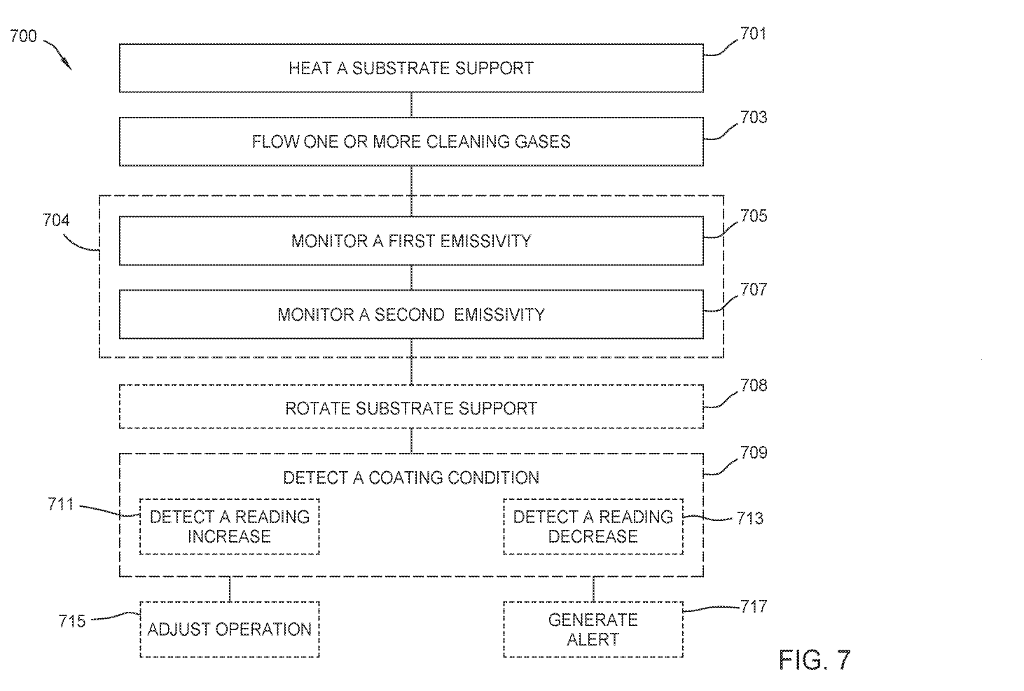

FIG. 7 is a schematic block diagram view of a method 700 of chamber cleaning, according to one or more embodiments. The method 1100 can be conducted, for example, before or after the method 600 of substrate processing.

The method 700 is described in relation to the sensor assembly 400 shown in FIGS. 4 and 5. The present disclosure contemplates that the method 700 can be conducted in relation to other systems and apparatus.

Operation 701 of the method 700 includes heating the substrate support.

Operation 703 includes flowing one or more cleaning gases over the plate and/or the substrate support to remove a coating from the plate and/or the substrate support. The one or more cleaning gases can flow, for example through the lower portion 136a and/or the upper portion 136b.

Operation 705 includes monitoring a first emissivity of the substrate support 106 through a first filter of the filters 421-430. In one or more embodiments, the monitoring of the first emissivity includes detecting energy having a first wavelength within a range of 3.1 microns to 3.5 microns.

Operation 707 includes monitoring a second emissivity of the plate 171 through a second filter of the filters 421-430. In one or more embodiments, the monitoring of the second emissivity includes detecting energy having a second wavelength within a range of 2.5 microns to 3.0 microns. In one or more embodiments, the first emissivity and/or second emissivity are monitored and used as part of processing map(s).

In one or more embodiments, operation 705 and 707 are a part of operation 704, which includes rotating the movable tray 410 to shift the respective filters 421-430 into alignment with an optical path of at least one of the optical sensors 196-198 (such as the camera of the first optical sensor 196 and/or the camera of the second optical sensor 197).

Optional operation 709 includes detecting a cleaning condition for the plate. In one or more embodiments, the detecting of the cleaning condition includes (at operation 711) detecting a reading increase through one of the filters 621-630, and (at operation 713) detecting a reading decrease through another of the filters 421-430 at the same radial location of the reading decrease. In one or more embodiments, the cleaning condition is a second pre-determined thickness (e.g., lower than the pre-determined thickness of the coating condition). At the cleaning condition, the coating on the plate is reduced to or below the second pre-determined thickness.

Optional operation 715 includes an adjusting operation. The adjusting can include one or more of: adjusting an operating parameter (such as an input power supplied to at least one of the heat sources of the chamber); halting the cleaning of operation 703, initiating a chamber downtime period; initiating a preventive maintenance operation (such as including an open chamber operation); delaying a subsequent iteration of the cleaning, and/or initiating a deposition operation using a deposition recipe (such as the operation 603 of the method 600 to deposit layer(s) on the substrate).

Optional operation 717 includes generating an alert. For example, the alert may indicate that the cleaning of operation 703 can end. In one or more embodiments, the alert instructs an operator (such as on a display of a user interface) to initiate deposition operations.

The information of the method 600 and/or the method 700 (such as temperature measurements, intensity measurements in images, reading increases, and/or reading decreases) can be stored and tracked as data. In one or more embodiments, the data is analyzed and/or compared using averages, derivatives, modeling, imaging, and/or with other data analysis techniques. As an example, the first and second optical sensors 196, 197 can capture images, and the intensity of the images can be analyzed for detection of the first and second temperatures.

Benefits of the present disclosure include accurate, quick, efficient, and automatic detection of processing parameters (such as temperatures, film thicknesses, coating conditions, and/or cleaning conditions) for a variety of chamber components (such as the substrate 102, the substrate support 106, and/or the plate 171); reduced diversive flow of gases away from the substrate 102 and the substrate support 106; adjustability of parameters (such as temperatures, gas flow paths, gas flow rates, and/or gas pressures) across a variety of operation conditions (such as low rotation speeds, high pressures, and/or low flow rates); broader and/or more modular ranges of adjustability; and increased deposition uniformity. Benefits of the present disclosure also include reduced chamber footprints; reduced or eliminated chamber component contamination; reduced cleaning, and increased ease of cleaning; increased component lifespan; reduced chamber downtime; and increased throughput. Benefits of the present disclosure also include enhanced deposition repeatability and/or cleaning repeatability.

As an example, the subject matter facilitates real-time uniformity monitoring of a variety of chamber components at various locations, real-time monitoring of processing effects of changes in processing parameters (such as flow rate parameters, cooling parameters, and/or heating parameters), and real-time monitoring of variation in processing (such as heating) with reduced or eliminated delays. As a further example, the subject matter can be used to identify heat sources (such as lamps) that age and/or fail. As another example, the implementations of the present disclosure are modular and can be used across a variety of processing (e.g., deposition) operations and/or cleaning operations, including across a variety of operation parameters. As an additional example, the subject matter can monitor relatively small (such as 0.1 degree Celsius) temperature variations.

It is contemplated that one or more aspects disclosed herein may be combined. As an example, one or more aspects, features, components, operations and/or properties of the processing chamber 100, the controller 190, at least one of the one or more sensors 195, 196, 197, 198, the sensor assembly 400, the movable tray 410, the filters 421-430, the motor controller 440, the method 600, and/or the method 700 may be combined. For example, the operations and/or parameters described in relation to FIG. 1 and FIG. 4 can be combined with the operations and/or the parameters of the method 600 and/or the method 700. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A system for processing substrates and applicable for semiconductor manufacturing, the system comprising:
a chamber body at least partially defining an internal volume;
one or more heat sources configured to heat the internal volume;
a substrate support disposed in the internal volume; and
a sensor assembly operable to measure energy of a plurality of wavelengths in the internal volume, the sensor assembly comprising:
one or more optical sensors,
a movable tray coupled to a motor, and
a plurality of filters supported by the movable tray, the motor operable to move the movable tray to move the plurality of filters relative to the one or more optical sensors to respectively align the plurality of filters with at least one of the one or more optical sensors.

2. The system of claim 1, wherein the movable tray comprises a plurality of holes disposed below the plurality of filters.

3. The system of claim 2, wherein the movable tray further comprises a mirror oriented at an angle relative to a plate of the movable tray, the mirror extending above at least one of the plurality of filters, wherein the movable tray is a rotatable wheel.

4. The system of claim 1, wherein the sensor assembly further comprises a probe aligned with at least one of the plurality of filters, the movable tray is movable relative to the probe, and the probe comprises a view lens and a focus lens disposed between the view lens and the movable tray.

5. The system of claim 1, wherein the plurality of filters comprise:
a first filter configured to transmit a first wavelength within a range of 2.5 microns to 3.0 microns; and
a second filter configured to transmit a second wavelength within a range of 4.5 microns to 5.5 microns.

6. The system of claim 5, further comprising:
a first quartz plate disposed between the substrate support and the one or more heat sources; and
a second quartz plate disposed between the first quartz plate and the one or more heat sources.

7. The system of claim 1, wherein the plurality of filters comprise:
a first filter configured to transmit a first wavelength within a range of 0.8 microns to 1.4 microns; and
a second filter configured to transmit a second wavelength within a range of 3.1 microns to 3.5 microns.

8. The system of claim 7, further comprising a controller comprising instructions that, when executed, cause a plurality of operations to be conducted, the plurality of operations comprising:
heating a substrate supported at least partially by the substrate support;
flowing one or more process gases over the substrate to form one or more layers on the substrate;
monitoring a first emissivity of the one or more heat sources using the first wavelength transmitted through the first filter; and
monitoring a second emissivity of the substrate or the substrate support using the second wavelength transmitted through the second filter.

9. A system for processing substrates and applicable for semiconductor manufacturing, the system comprising:
a chamber body at least partially defining an internal volume;
one or more heat sources configured to heat the internal volume;
a substrate support disposed in the internal volume; and
a sensor assembly operable to measure energy of a plurality of wavelengths in the internal volume, the sensor assembly comprising:
a probe comprising a view lens oriented toward the substrate support,
a camera in optical communication with the probe,
a rotatable wheel coupled to a motor, and
a plurality of filters supported by the rotatable wheel, the motor operable to move the rotatable wheel to move the plurality of filters relative to the camera to respectively align the plurality of filters with the camera.

10. The system of claim 9, wherein the camera comprises a graphene sensor operable to sense energy within a wavelength range that is 400 nm to higher than 5.0 microns.

11. The system of claim 9, wherein the rotatable wheel further comprises a mirror oriented at an angle relative to a plate of the rotatable wheel, the mirror extending above at least one of the plurality of filters.

12. The system of claim 9, wherein the plurality of filters comprise:
a first filter configured to transmit a first wavelength within a range of 2.5 microns to 3.0 microns;
a second filter configured to transmit a second wavelength within a range of 4.5 microns to 5.5 microns;
a third filter configured to transmit a third wavelength within a range of 0.8 microns to 1.4 microns; and
a fourth filter configured to transmit a fourth wavelength within a range of 3.1 microns to 3.5 microns.

13. The system of claim 9, further comprising a controller comprising instructions that, when executed, cause a plurality of operations to be conducted, the plurality of operations comprising:
heating a substrate supported at least partially by the substrate support;
flowing one or more process gases over the substrate to form one or more layers on the substrate; and
rotating the rotatable wheel to shift the respective filters into alignment with an optical path of the camera.

14. The system of claim 13, wherein the plurality of operations further comprise rotating the substrate support at a first speed that is greater than a second speed of the rotatable wheel.

15. The system of claim 14, wherein the second speed is equal to or lesser than a value, and the value is equal to a frame rate of the camera multiplied by a number of the plurality of filters.

16. The system of claim 9, wherein the plurality of filters comprise a red lens, a green lens, and a blue lens.

17. A system for processing substrates and applicable for semiconductor manufacturing, the system comprising:
a chamber body at least partially defining an internal volume;
one or more heat sources configured to heat the internal volume;
a substrate support disposed in the internal volume;
a sensor assembly operable to measure energy of a plurality of wavelengths in the internal volume, the sensor assembly comprising:
a camera,
a rotatable wheel coupled to a motor, and
a plurality of filters; and
a controller comprising instructions that, when executed, cause a plurality of operations to be conducted, the plurality of operations comprising:
heating a substrate supported at least partially by the substrate support;
flowing one or more process gases over the substrate to form one or more layers on the substrate; and
rotating the rotatable wheel to shift the respective filters into alignment with an optical path of the camera.

18. The system of claim 17, wherein the plurality of filters comprise:
a first filter configured to transmit a first wavelength within a range of 2.5 microns to 3.0 microns when in the optical path of the camera; and
a second filter configured to transmit a second wavelength within a range of 4.5 microns to 5.5 microns when in the optical path of the camera.

19. The system of claim 17, wherein the plurality of filters comprise:
a first filter configured to transmit a first wavelength within a range of 0.8 microns to 1.4 microns when in the optical path of the camera; and
a second filter configured to transmit a second wavelength within a range of 3.1 microns to 3.5 microns when in the optical path of the camera.

20. The system of claim 17, wherein the rotatable wheel further comprises a mirror oriented at an angle relative to a plate of the rotatable wheel, the mirror extending above at least one of the plurality of filters.
